(19) United States
(12) Patent Application Publication
(10) Pub. No.: US 2020/0135994 A1
(43) Pub. Date: Apr. 30, 2020

(54) Optoelectronic Semiconductor Component and Production Method

(71) Applicant: OSRAM Opto Semiconductors GmbH, Regensburg (DE)

(72) Inventors: Korbinian Perzlmaier, Regensburg (DE); Christine Rafael, Donaustauf (DE); Ivar Tangring, Regensburg (DE)

(21) Appl. No.: 16/493,415

(22) PCT Filed: Mar. 20, 2018
(86) PCT No.: PCT/EP2018/057001

§ 371 Date: Sep. 12, 2019

(30) Foreign Application Priority Data
Mar. 27, 2017 (DE) 10 2017 106 508.3

(51) Int. Cl. H01L 33/60; H01L 33/62; H01L 33/50

(52) U.S. Cl. CPC H01L 33/60; H01L 33/62; H01L 2933/005; H01L 2933/0058; H01L 33/505

(57) ABSTRACT

An optoelectronic semiconductor component and a production method are disclosed. In an embodiment an optoelectronic semiconductor component includes a light-emitting diode chip including a semiconductor layer sequence configured to generate radiation, electrical contact points on a mounting side, a carrier body and an anti-wetting layer being exposed laterally at the light-emitting diode chip and being located between the semiconductor layer sequence and the carrier body and/or being located in a lateral direction next to the semiconductor layer sequence, a filling permeable to the radiation and a reflector for the radiation, wherein the anti-wetting layer has a repellent effect on at least one of a material of the reflector or of the filling, and wherein the filling and the reflector adjoin each other at the exposed anti-wetting layer.

This patent application is a national phase filing under section 371 of PCT/EP2018/057001, filed Mar. 20, 2018, which claims the priority of German patent application 102017106508.3, filed Mar. 27, 2017, each of which is incorporated herein by reference in its entirety.

### TECHNICAL FIELD

An optoelectronic semiconductor component and a production method therefor are provided.

### SUMMARY OF THE INVENTION

Embodiments provide an optoelectronic semiconductor component from which light is efficiently coupled out.

According to at least one embodiment, the optoelectronic semiconductor component comprises one or more light-emitting diode chips. The at least one light-emitting diode chip is designed to generate radiation, in particular visible light. For example, the light emitting diode chip emits blue light during operation, in particular with a wavelength of maximum intensity of at least 420 nm and/or of at most 480 nm.

According to at least one embodiment, the semiconductor component comprises a filling. The filling is permeable to the radiation to be generated, in particular clear.

According to at least one embodiment, the semiconductor component comprises a reflector. The reflector is designed for diffuse and/or specular reflection of the radiation to be generated. For example, the reflector appears white to be a viewer.

According to at least one embodiment, the light-emitting diode chip comprises a semiconductor layer sequence. An active zone for generating the radiation is located in the semiconductor layer sequence.

The semiconductor layer sequence is preferably based on a III-V compound semiconductor material. The semiconductor material is a nitride compound semiconductor material such as AlₙIn₁₋ₙ₋ₘGaₘN or a phosphide compound semiconductor material such as AlₙIn₁₋ₙ₋ₘGaₘP or an arsenide compound semiconductor material such as AlₙIn₁₋ₙ₋ₘGaₘAs or AlₙGaₘIn₁₋ₙ₋ₘAsₖP₁₋ₖ, wherein 0≤n≤1, 0≤m≤1 and n+m≤1 as well as 0≤k<1. Preferably, for at least one layer or for all layers of the semiconductor layer sequence 0<n≤0.8, 0.4≤m<1 and n+m≤0.95 as well as 0<k≤0.5 apply. The semiconductor layer sequence can have doping substances and additional constituents. For the sake of simplicity, however, only the essential components of the crystal lattice of the semiconductor layer sequence are mentioned, that is Al, As, Ga, In, N or P, even if these can be partially replaced and/or supplemented by small amounts of other substances.

According to at least one embodiment, the light-emitting diode chip has electrical contact points, in particular exactly two electrical contact points. The light-emitting diode chip and thus the semiconductor component can be externally electrically and/or mechanically contacted via the electrical contact points. The contact points are preferably formed by one or more metal layers and can preferably be connected by soldering. The electrical contact points are located on a mounting side of the light-emitting diode chip which at the same time represents a mounting side of the semiconductor component.

According to at least one embodiment, the light-emitting diode chip has a carrier body. The carrier body can mechanically support and stabilize the light-emitting diode chip and can be the component which mechanically supports the light-emitting diode chip, so that the light-emitting diode chip is not mechanically stable without the carrier body. The carrier body can be formed by a cast body and can be produced by means of casting, in particular by means of compression molding, injection molding or transfer molding.

According to at least one embodiment, the light-emitting diode chip has one or more anti-wetting layers. The at least one anti-wetting layer is repellent to a material of the reflector and/or of the filling. That is, a contact angle of the material of the reflector and/or of the filling is at the anti-wetting layer at least 80° or 85° or 90°. The anti-wetting layer is thus not wettable by a material of the filling and/or of the reflector.

According to at least one embodiment, the anti-wetting layer is laterally exposed at the light-emitting diode chip. This means that the anti-wetting layer is freely accessible in places outside the light-emitting diode chip, in particular before the filling and/or the reflector are molded onto the light-emitting diode chip.

According to at least one embodiment, the wetting layer is laterally exposed in a region, in which the reflector and the filling butt against one another and preferably form an interface. In particular, during production of the filling and/or of the reflector, the anti-wetting layer prevents that the material of the reflector and/or of the filling passes significantly over the anti-wetting layer. For example, smaller threads or noses of the material of the reflector and/or of the filling can extend over the anti-wetting layer. Such threads or noses preferably make up a proportion of at most 1% or 5% of the filling and/or the reflector. Alternatively or in addition, the anti-wetting layer remains in a length proportion of at least 90% or 95% or 98% as a defined separation line between the reflector and the filling.

According to at least one embodiment, the anti-wetting layer, in particular the laterally exposed region of the anti-wetting layer, is located between the semiconductor layer sequence and the carrier body. Alternatively or additionally, this region of the anti-wetting layer is located in the lateral direction next to the semiconductor layer sequence. The lateral direction in particular means a direction parallel to the plane of the semiconductor layer sequence and/or perpendicular to a main radiation direction and/or the mounting side of the light-emitting diode chip. If the anti-wetting layer is located laterally next to the semiconductor layer sequence, then the semiconductor layer sequence and the anti-wetting layer are particularly preferably located in a common plane.

According to at least one embodiment, an interface between the filling and the reflector is formed in a reflecting manner and is configured to reflect the radiation to be generated in the direction away from the carrier body. This means that the interface is oriented obliquely with respect to the mounting side. The filling forms in particular a funnel like a truncated pyramid or a truncated cone, which extends in the direction away from the mounting side and thus in the direction away from the carrier body. The funnel can have straight or curved side faces as seen in cross-section. That the interface is formed in a reflecting manner does not necessarily exclude that the radiation to be reflected penetrates into the reflector up to a low depth and is only reflected at a certain depth of, for example, at most 300 μm or 100 μm, in particular if the reflector is diffusely reflecting and/or is formed by a matrix material with particles embedded therein. An intensity of the radiation to be reflected can decrease exponentially from the interface into the reflector.

In at least one embodiment, the semiconductor component comprises a light-emitting diode chip for generating radiation and also a filling, which is permeable to the radiation. The semiconductor component also has a reflector for the radiation. The light-emitting diode chip comprises a semiconductor layer sequence for generating the radiation, electrical contact points on a mounting side, a carrier body and an anti-wetting layer. The anti-wetting layer acts repellent for a material of the reflector and/or the filling. The anti-wetting layer is laterally exposed at the light-emitting diode chip and is located between the semiconductor layer sequence and the carrier body and/or in the lateral direction next to the semiconductor layer sequence. The filling and the reflector abut against each other on the exposed anti-wetting layer. The filling widens in the direction away from the mounting side, so that in particular at a boundary surface between the filling and the reflector reflection of the radiation in the direction away from the carrier body takes place.

With the semiconductor component described here it is possible to achieve an optimization of the yield from light which is coupled out at sides the semiconductor layer sequence, that is to say coupled out laterally. In the area of side surfaces of the semiconductor layer sequence on an upper side of the carrier body, that is between the carrier and the semiconductor layer sequence, an anti-wetting layer is inserted, which is only poorly wetted or not at all wetted by the material used, in particular, for the filling, said material is preferably a clear silicone. Thus, a meniscus does not form as far as the mounting side, but only from a light exit side to the anti-wetting layer.

This prevents the generated radiation from reaching the absorbent lateral surfaces of the carrier body, because the side surfaces of the carrier body are not wetted by the material of the light-permeable filling. The anti-wetting layer is preferably a metal layer, which is exposed during singulation of the light-emitting diode chips by sawing or scoring and breaking. The anti-wetting layer can be refined by a method such as electroless plating or an immersion method. For example, the anti-wetting layer is a nickel layer or a copper layer which is provided with palladium, tin and/or gold.

Silicones adhere only poorly to metals, in particular to gold. It is thus possible to realize a comparatively thin anti-wetting layer which does not or does not significantly impair the rest of the structure of the light-emitting diode chip. A shape of the reflector can thus be generated as a result of the anti-wetting layer and an improved light yield from the light-emitting diode chip and the semiconductor component can be achieved, connected with an increase in efficiency.

According to at least one embodiment, the semiconductor component comprises one or more luminous substance bodies. The at least one luminous substance body is located on a chip top side of the light-emitting diode chip facing away from the mounting side, in particular exclusively on the chip top side. The luminous substance body contains one or more phosphors for partial or complete conversion of the radiation generated in the light-emitting diode chip into a radiation of a longer wavelength. For example, blue light is partially converted into yellow light so that white light is emitted by the semiconductor component as a whole.

The luminous substance body can contain inorganic luminescent substances such as YAG:Ce or also organic phosphors or quantum dots. It is also possible for the luminous substance body to be epitaxially grown and to contain absorbing layers, which produce the longer-wave radiation by means of photoluminescence. In particular, if ceramic phosphors are present, they can be directly linked to one another and can form a ceramic luminescent body or can also be embedded in a matrix material made of a plastic, a glass or a ceramic. The luminous substance body can comprise or consist of a luminous substance layer or a plurality of luminous substance layers or additionally a luminous substance support layer in the form of a plate made of glass, plastic or sapphire, for example.

According to at least one embodiment, side surfaces of the luminous substance body are covered directly by the filling. The side surfaces are preferably oriented perpendicular or approximately perpendicular to the mounting side and represent front faces of the luminous substance body.

According to at least one embodiment, the luminous substance body is spaced apart from the reflector. This means that the luminous substance body and the reflector do not touch each other. In particular, the reflector and the luminous substance body are separated from one another by the filling.

According to at least one embodiment, the luminous substance body terminates flush with the filling in the direction away from the mounting side. The luminous substance body and the filling can together form a surface, which is flat and which can be oriented parallel to the mounting side.

According to at least one embodiment, a top face of the luminous substance body facing away from the mounting side is free of the filling and alternatively or additionally free of the reflector. In other words, the filling and/or the reflector can be limited to a region laterally next to the luminous substance body.

According to at least one embodiment, the anti-wetting layer is electrically separated from the contact points. It is possible for the anti-wetting layer to also be electrically separated from the semiconductor layer sequence. The anti-wetting layer can be electrically insulated from all the electrically functionalized components of the light-emitting diode chip and the semiconductor component.

According to at least one embodiment, the anti-wetting layer is formed by one or more metal layers or consists of one or more metal layers. In particular, the anti-wetting layer comprises one or more of the following metals or consists of one or more of these metals: gold, copper, nickel, palladium, tin. The anti-wetting layer is preferably a gold layer or a comparatively thick copper layer, which is provided with a thinner gold layer.

According to at least one embodiment, the anti-wetting layer is made thin. This means, for example, that the anti-wetting layer has a thickness of at least 20 nm or 50 nm at chip side surfaces of the light-emitting diode chip. Alternatively or additionally, the thickness of the anti-wetting layer at the chip side surfaces is at most 5 μm or 1 μm or 500 nm or 200 nm or 100 nm.

According to at least one embodiment, the anti-wetting layer is a part of a mirror or a mirror system for the radiation to be generated in the light-emitting diode chip. For example, the anti-wetting layer is a metallic mirror layer which is led out or led further to the chip side surfaces. In this case, the anti-wetting layer is preferably free of silver, in particular at the laterally exposed area.

According to at least one embodiment, the anti-wetting layer is spaced apart from the semiconductor layer sequence. This means that the anti-wetting layer and the semiconductor layer sequence do not touch each other. Alternatively, it is possible for the anti-wetting layer and the semiconductor layer sequence to be in direct contact with each other, within the light-emitting diode chip and/or on the side surfaces of the chip.

According to at least one embodiment, the reflector is formed by a potting body. The reflector preferably consists of a matrix material and particles embedded therein. The matrix material can be transparent to the radiation to be generated in the light-emitting diode chip, in particular clear. The particles are light-scattering or reflecting particles. In particular in this case, the reflector can act diffusely reflecting for the radiation to be generated.

According to at least one embodiment, the reflector terminates flush with the contact points in the direction perpendicular to the mounting side. This means that the mounting side can extend continuously in a common plane over the cast body and the carrier body as well as optionally the electrical contact points. This applies in particular with a tolerance in the direction perpendicular to the mounting side of at most 10 μm or 5 μm or 2 μm or 0.5 μm.

According to at least one embodiment, the filling is formed from a phenyl silicone. The filling preferably has a comparatively high refractive index for the radiation to be generated, for example, a refractive index of at least 1.46 or 1.5, at to room temperature and at a wavelength of maximum intensity of the radiation to be generated.

According to at least one embodiment, the matrix material is formed from a methyl silicone or comprises such a material. The matrix material can have a comparatively low refractive index for the radiation to be generated. The refractive index of the matrix material is in particular at least 0.05 or 0.1 lower than the refractive index of the filling.

According to at least one embodiment, the reflector is formed by a mirror layer. The mirror layer can be a metal layer or a dielectric layer sequence. The mirror layer is preferably specularly reflective, so that an angle of incidence of the radiation to be reflected is equal to an emergent angle.

According to at least one embodiment, the mirror layer has a small thickness. In particular the thickness of the mirror layer is at least 50 nm or 100 nm or 150 nm. Alternatively or additionally, the mirror layer has a thickness of at most 3 μm or 2 μm or 1 μm or 0.5 μm. In comparison with a reflector which is formed by a potting body, the mirror layer is thus very thin.

According to at least one embodiment, the chip side surfaces of the light-emitting diode chip are formed by the carrier body, at least on the mounting side. The carrier body is preferably a cast body made, for example, of an epoxide. The cast body and/or the carrier body can act to absorb the radiation to be generated and, for example, can be dark, in particular, can be grey or black.

According to at least one embodiment, the filling is spaced apart from the cast body and/or the carrier body. This is achieved in particular by the anti-wetting layer.

According to at least one embodiment, the chip side surfaces are covered directly and preferably completely by the reflector in the region of the carrier body and/or of the cast body.

According to at least one embodiment, the reflector is electrically separated from the electrical contact points and/or the semiconductor layer sequence. In particular in the case of an electrically conductive reflector, specially formed by the mirror layer, short circuits can thus be prevented.

According to at least one embodiment, the filling and/or the reflector are partially or completely covered by a light-decoupling body such as a lens and/or a plate on a side facing away from the mounting side. The lens and/or the plate are made of a glass or a plastic such as a silicone, an epoxide or an acryl. Such a plate, in particular a glass plate, can represent a supporting component of the semiconductor component. The lens is preferably designed as a collecting lens.

According to at least one embodiment, an average angle of the interface with respect to a main radiation direction of the light-emitting diode chip is at least 30° or 40° or 50°. Alternatively or additionally, this average angle is at most 75° or 70° or 65°, in particular approximately 60°. Preferably it applies to each partial section of the interface that an angle of the partial section in question with respect to the main radiation direction is at least 25° or 35° and/or at most 80° or 70°. This means that the interface then does not have partial sections which are aligned approximately parallel or perpendicular to the main radiation direction.

According to at least one embodiment, the filling has an extension of at least 1 μm or 2 μm or 5 μm in the direction perpendicular to the mounting side. Alternatively or additionally, this extension is at most 100 μm or 50 μm or 20 μm.

According to at least one embodiment, the filling extends in the direction perpendicular to the mounting side over at least 0.5% or 2% or 10% of an overall thickness of the light-emitting diode chip. Alternatively or additionally, this value is at most 50% or 40% or 25%. The filling is preferably exclusively located at a region which is furthest from the mounting side.

According to at least one embodiment, an extension of the filling along the lateral direction is at least 2 μm or 10 μm and/or at most 200 μm or 100 μm or 40 μm or 20 μm. Alternatively or additionally, along the lateral direction the filling has an extent of at most 50% or 25% or 15% or 10% or 5% of a total width of the light-emitting diode chip. Alternatively or additionally, this extent is at least 0.1% or 0.5% or 1%. That is, along the lateral direction the filling occupies only a comparatively small proportion, in relation to a total width of the light-emitting diode chip and thus also to a total width of the semiconductor component.

Moreover, a method for producing an optoelectronic semiconductor component, as described in connection with one or more of the above-mentioned embodiments, is provided. Features of the optoelectronic semiconductor component are therefore also disclosed for the method and vice versa.

In at least one embodiment, one or more optoelectronic semiconductor components are produced with the method. The method comprises the following steps, preferably in the order given: A) providing a light-emitting diode chip for generating radiation, the light-emitting diode chip has a semiconductor layer sequence for generating the radiation, has electrical contact points arranged on a mounting side, has a carrier body and has an anti-wetting layer, B) producing either a filling which is permeable to the radiation to be generated, or a reflector for the radiation to be generated, the anti-wetting layer has a repellent effect for a material of the reflector or of the filling, and C) producing the reflector or the filling, depending on which element has not yet been produced in step B), wherein—in step B), the anti-wetting layer is exposed laterally at the light-emitting diode chip and is located between the semiconductor layer sequence and the carrier body and/or is located in a lateral direction next to the semiconductor layer sequence, so that the anti-wetting layer is a boundary line for a material of the filling or of the reflector, and—the filling and the reflector are produced directly abutting one another and the filling widens along the direction away from the mounting side so that reflection of the radiation in the direction away from the carrier body takes place in particular at an interface between the filling and the reflector.

The anti-wetting layer can optionally be removed between steps B) and C), for example, by means of etching. Preferably, however, the anti-wetting layer is retained, so that the anti-wetting layer is still present in the finished semiconductor component.

### BRIEF DESCRIPTION OF THE DRAWINGS

In the following, an optoelectronic semiconductor component described here is explained in more detail with reference to the drawing by means of exemplary embodiments. The same reference signs indicate the same elements in the figures. However, no references true to scale are shown; rather, individual elements may be represented with an exaggerated size for the sake of better understanding.

In the figures:

FIGS. 1A and 4A are schematic sectional views of light-emitting diode chips for semiconductor components;

FIGS. 1B and 4B are schematic side views of light emitting diode chips for semiconductor components;

FIGS. 2, 3 and 5 to 10 are schematic sectional views of exemplary embodiments of optoelectronic semiconductor components; and

FIGS. 11 and 12 show schematic sectional representations of modifications of semiconductor components.

### DETAILED DESCRIPTION OF ILLUSTRATIVE EMBODIMENTS

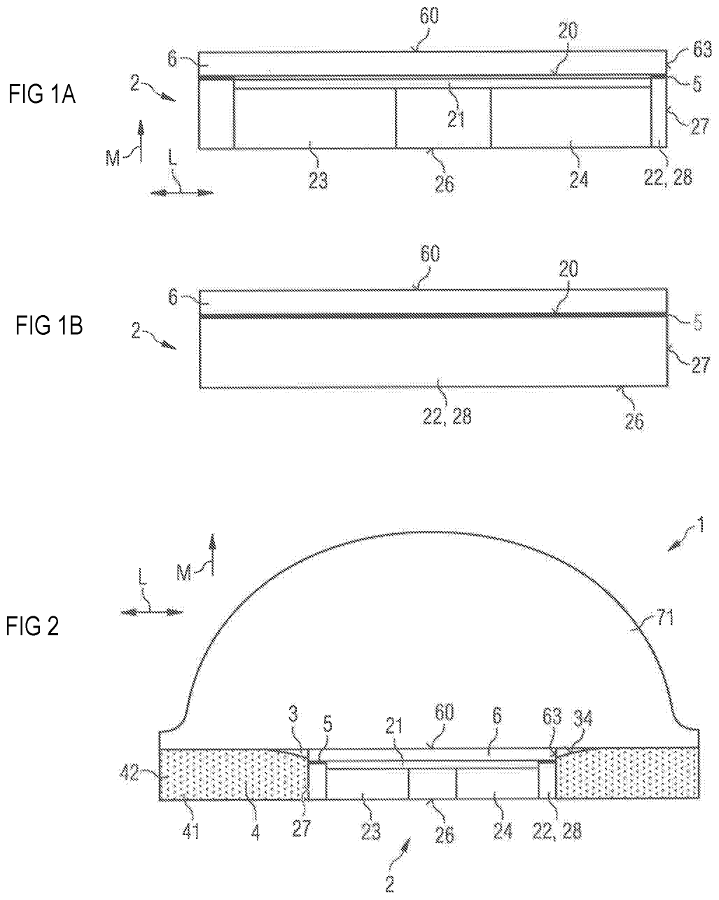

FIG. 1 illustrates a light-emitting diode chip 2 for embodiments of optoelectronic semiconductor components 1, compare the sectional representation of FIG. 1A and the side view of FIG. 1B.

The light-emitting diode chip 2 comprises a semiconductor layer sequence 21 with an active zone (not shown) for generating radiation. The semiconductor layer sequence 21 is located on a carrier body 22 which is preferably a cast body 28. The carrier body 22 is made, for example, of a black epoxide. The carrier body 22 and the semiconductor layer sequence 21 are provided with electrical contact points 23, 24 for external electrical and mechanical mounting of the semiconductor component 1. A mounting side 26 is formed by the contact points 23, 24 together with the cast body 28. On the mounting side 26, chip side surfaces 27 are also realized by the cast body 28.

The semiconductor layer sequence 21 does not extend as far as the chip side surfaces 27. In a lateral direction L, that is in the direction parallel to a main extension direction of the semiconductor layer sequence 21 and in the direction parallel to the mounting side 26, between the chip side surfaces 27 and the semiconductor layer sequence 21 there is an anti-wetting layer 5. The anti-wetting layer 5 is, for example, a metallic layer or a metallic layer sequence with a comparatively small thickness.

The anti-wetting layer 5 can directly adjoin the cast body 28, in the direction towards the mounting side 26. The anti-wetting layer 5 and the semiconductor layer sequence 21 are thus located in a common plane. A continuous path is formed by the anti-wetting layer 5 on the chip side surfaces 27, said path limits the cast body 28 in the direction away from the mounting side 26, see in particular FIG. 1B.

Side surfaces of the semiconductor layer sequence 21 can be completely covered by the cast body 28 together with the anti-wetting layer 5, as seen in a side view. It is possible for the semiconductor layer sequence 21 to terminate flush or approximately flush with the contact points 23, 24, along the lateral direction L.

For example, the light-emitting diode chip 2 is designed as provided in International Publication No. WO 2017/017209 A1, see in particular FIG. 5C and the associated description. In particular, the anti-wetting layer is realized by the layer with reference numeral 30 in FIG. 5C of this document. The disclosure content of this document, in particular with respect to FIG. 5C, is incorporated by reference.

It is also possible for the light-emitting diode chip to be designed as indicated in International Publication No. WO 2016/113032 A1, see in particular FIG. 1 and the associated description. The anti-wetting layer can be formed by the layer with the reference numeral 6 in FIG. 1 of this document, wherein this layer is preferably pulled out as far as the side surfaces. The disclosure content of this document, in particular with respect to FIG. 1 and the associated description, is incorporated by reference.

Along the main radiation direction M, which is oriented perpendicular to the mounting side 26, a luminous substance body 6 is arranged downstream of the light-emitting diode chip 2, preferably over the whole area. That is, the luminous substance body 6 covers a chip top side 20 completely. A top face 60 of the luminous substance body 6 faces away from the mounting side 26. Side surfaces 63 of the luminous substance body 6 are aligned approximately perpendicular to the mounting side 26.

FIG. 2 shows an embodiment of the semiconductor component 1 in which the light-emitting diode chip 2 of FIG. 1 is used. In addition to the light-emitting diode chip 2 and to the luminous substance body, the semiconductor component 1 comprises a transparent filling 3 and a reflector 4. As an option, there is a lens 71, too.

The filling 3 is shaped as a fillet when viewed in cross-section. The filling 3 terminates flush with the top face 60 of the luminous substance body 6 in the direction away from the mounting side 26 and forms a common plane with this top face 60. In the direction of the mounting side 26, the filling 3 extends as far as the anti-wetting layer 5. Thus, an expansion of the filling 3 along the main radiation direction M is defined by the anti-wetting layer 5. An interface 34 between the filling 3 and the reflector 4 is concavely shaped. A diffuse reflection of the light produced in the semiconductor layer sequence 21 and guided through the luminous substance body 6 takes place at the interface 34 by means of the reflector 4 which appears white. In other words, the filling 3 is limited to the side surfaces 63 of the luminous substance body 6. Hence, no radiation reaches the absorbent cast body 28, thereby increasing the light output efficiency.

The reflector 4 is formed by a potting body. Light-scattering particles 42 are made, for example, of titanium dioxide and are embedded in a matrix material 41 made, for example, of a silicone such as a methyl silicone. The matrix material 41 can have a refractive index which is smaller than that of the material for the filling 3, which is, for example, a silicone such as a phenyl silicone.

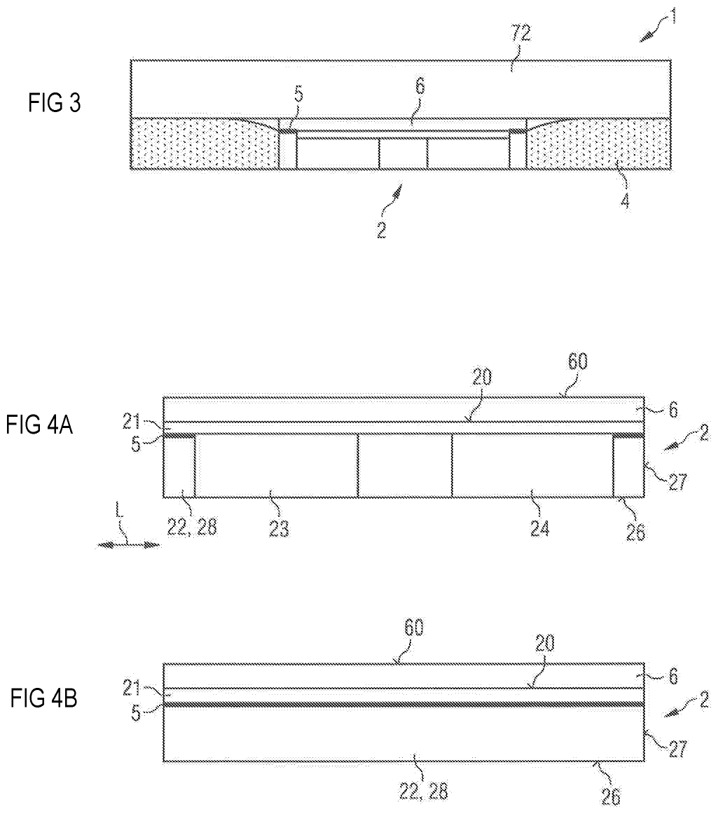

A glass plate 72 is provided instead of the lens 71 in the exemplary embodiment of FIG. 3. The glass plate 72 completely covers the reflector 4, the filling 3 and the luminous substance body 6. In other respects, the embodiment of FIG. 3 corresponds to that of FIG. 2.

A further light-emitting diode chip 2 for optoelectronic semiconductor components 1 described here is illustrated in FIGS. 4A and 4B. The semiconductor layer sequence 21 extends as far as the chip side surfaces 27. The semiconductor layer sequence 21 can be covered by a passivation layer (not shown) on the chip side surfaces 27.

The anti-wetting layer 5 is applied all around to the chip side surfaces 27 between the semiconductor layer sequence 21 and the cast body 28. The anti-wetting layer 5 can be applied as far as the contact points 23, 24 or, preferably, can be separated therefrom, so that the anti-wetting layer 5, as well as in all other embodiments, it is electrically insulated from the semiconductor layer sequence and/or the contact points 23, 24. The semiconductor layer sequence 21 as well as the anti-wetting layer 5 form a continuous frame on the chip side surfaces 27 around the light-emitting diode chip 2, see FIG. 4B.

The light-emitting diode chip 2 as well as the luminous substance body 6 of FIG. 4 correspond to that of FIG. 1.

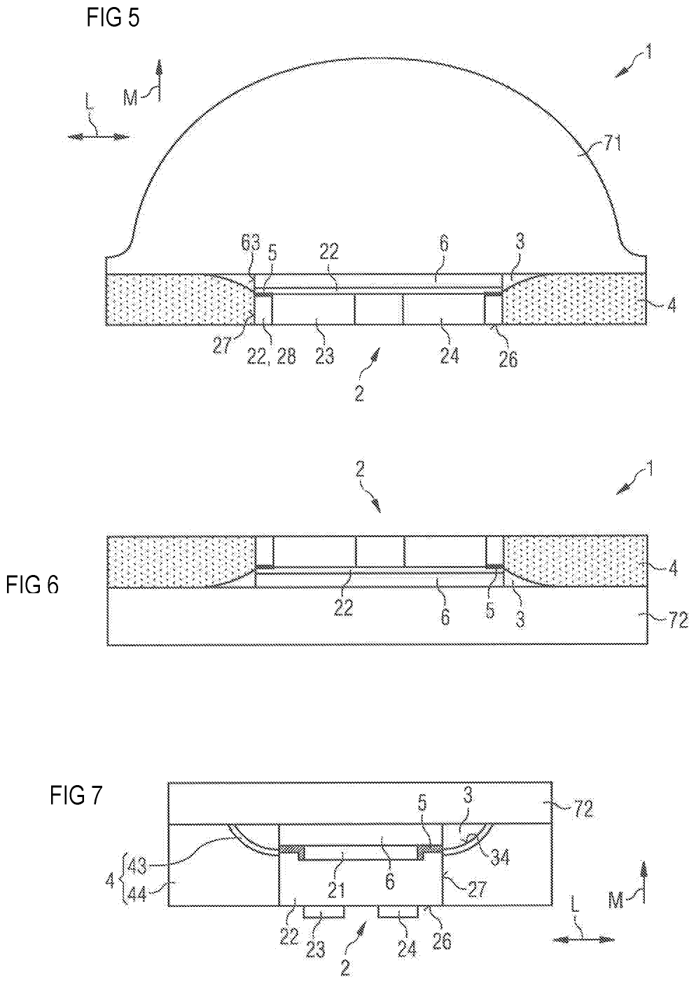

FIGS. 5 and 6 show exemplary embodiments of the semiconductor component 1, in a similar manner to FIGS. 2 and 3. Since the semiconductor layer sequence 21 extends as far as the chip side surfaces 27, the filling 3 on the side surfaces 27 of the chip extends over the semiconductor layer sequence 21 and correspondingly over the side surfaces 63 of the luminous substance body 6. The extent of the filling 3 along the main radiation direction M is thus greater than in FIGS. 2 and 3.

For the rest, the exemplary embodiments of FIGS. 5 and 6 correspond to those of FIGS. 2 and 3, with the difference that not the semiconductor chip according to FIG. 1, but the semiconductor chip according to FIG. 4 is installed.

In the exemplary embodiment of FIG. 7, the filling is shaped not concave, but convex. The same can apply to all other exemplary embodiments.

The anti-wetting layer 5 is L-shaped when seen in cross-section. Thus, the anti-wetting layer 5 completely covers side surfaces of the semiconductor layer sequence 21. In total, the anti-wetting layer 5 has a constant, unvarying thickness.

Other than in the previous exemplary embodiments, the electrical contact points 23, 24 protrude beyond the mounting side 26 and, thus, beyond the carrier body 22 and also the reflector 4. The same can apply to all other exemplary embodiments.

The reflector 4 is formed by a mirror layer 43, in particular a metallic layer. The mirror layer 43 preferably extends with a constant thickness across the filling 3. Deviating from the representation in FIG. 7, it is possible that the mirror layer 43 also covers the areas of the chip side surfaces 27 not covered by the filling 3 as well as the areas of the glass plate 72 which are not in contact with the filling 3 or with the luminous substance body 6, preferably in each case with a layer thickness which remains constant.

Optionally, the reflector 4 comprises a clear casting 44. The clear casting 44 together with the mirror layer 43 can be geometrically shaped in the same manner as the reflector in FIG. 2 or 3.

Instead of the reflectors 4 in the form of a potting body shown in the other figures, such reflectors 4 with a mirror layer 43 can also be used in each case.

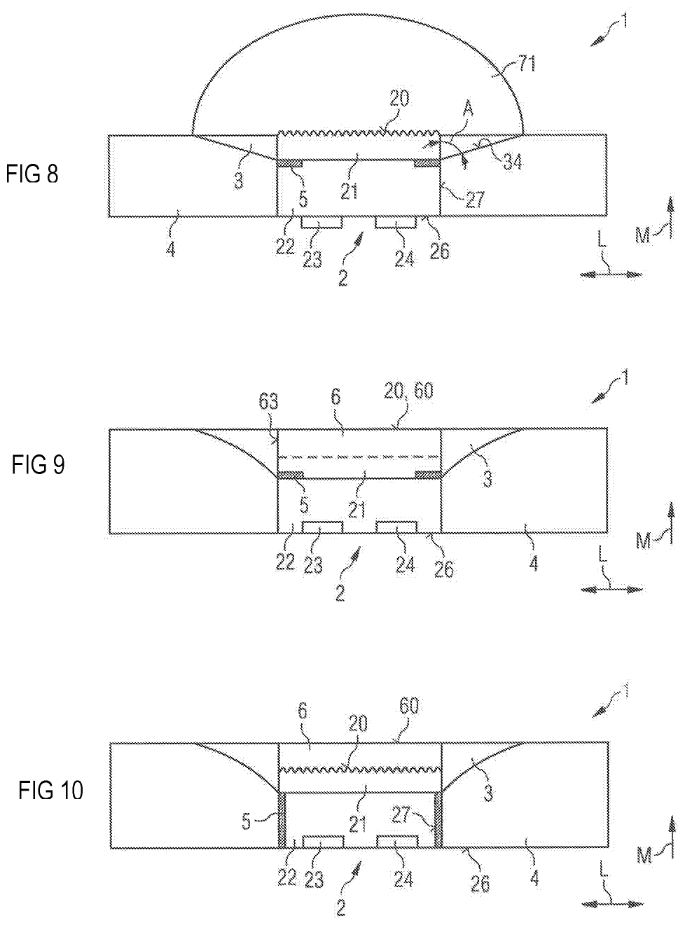

In the exemplary embodiment of FIG. 8, the filling 3 is triangular seen in cross-section. This can also be the case in all other exemplary embodiments. An average angle A between the interface 34 and the main radiation direction M is preferably approximately 60°.

There is no luminous substance body in the exemplary embodiment of FIG. 8. On the chip top side 20, there is a roughening for improving a light output efficiency. The roughening and thus the chip top side 20 are in direct contact with the optionally present lens 71. As well as in all other exemplary embodiments, it is possible that the lens 71 is limited to the filling 3.

A side of the semiconductor layer sequence facing the mounting side 26 is flat. On this side, the anti-wetting layer 5 is ring-shaped all around the chip side surfaces 27.

In the exemplary embodiment of FIG. 9, it is illustrated that the luminous substance body 6 is epitaxially grown and can be monolithically integrated in the semiconductor layer sequence 21. Therefore, in FIG. 9 the semiconductor layer sequence 21 with the not shown electroluminescent active zone and the photoluminescent luminous substance body 6 are separated from each other merely symbolically by a dashed line.

Further, an upper side of the carrier body 22 which is located closer to the chip top side 20, is of planar fashion. In this case, the chip top side 20 simultaneously represents the top face 60 of the luminous substance body 6. The anti-wetting layer 5 is applied to the upper side of the carrier body, as well as the semiconductor layer sequence 21. A corresponding configuration can also be present in all other exemplary embodiments.

In the exemplary embodiment of FIG. 10, the chip top side 20 is roughened and connected to the luminous substance body 6 by means of this roughening. As well as in all other exemplary embodiments it is possible that a connecting means (not shown), such as a silicone adhesive, is located between the luminous substance body 6 and the semiconductor layer sequence 21.

According to FIG. 10, the chip side surfaces 27 are completely covered by the anti-wetting layer 5 together with the filling 3. The anti-wetting layer 5 extends from the mounting side 26 to the semiconductor layer sequence 21. A corresponding design of the anti-wetting layer 5 is also possible in all other exemplary embodiments.

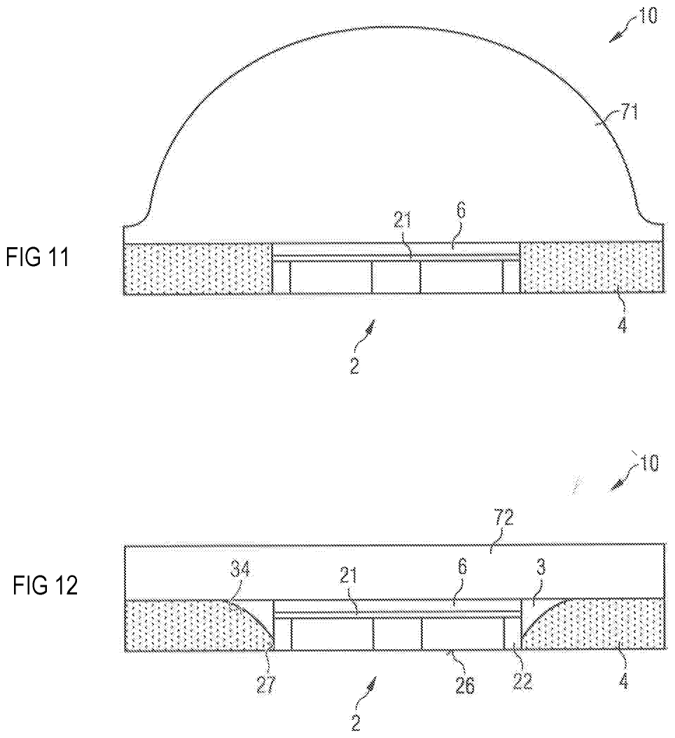

FIGS. 11 and 12 illustrate modifications 10 of semiconductor components. According to FIG. 11, there is no filling. As a result, the light generated is held longer in the semiconductor layer sequence 21 and the luminous substance body 6, so that greater absorption losses occur.

In contrast, although the modification 10 of FIG. 12 comprises the filling 3, but no anti-wetting layer 5. Thus, the filling 3 reaches the carrier body 22 and the side surfaces 27 of the carrier body 22 in a comparably undefined manner. Thus, a significant proportion of radiation passes to and can be absorbed by the carrier body 22. Hence, efficiency is reduced.

The components shown in the figures follow, unless indicated otherwise, preferably in the order given in each case directly on top of one another. Layers which are not touching in the figures are arranged at a distance from each other. As far as lines are drawn parallel to one another, the corresponding surfaces are likewise aligned parallel to one another. The relative thickness ratios, length ratios and the positions of the shown elements in relation to one another are correctly reproduced in the figures, unless indicated otherwise.

The invention is not limited by the description with reference to the exemplary embodiments. Rather, the invention includes any new feature and any combination of features, which in particular includes any combination of features in the patent claims, even if that feature or combination itself is not explicitly mentioned in the patent claims or exemplary embodiments.

1-15. (canceled)

16. An optoelectronic semiconductor component comprising:
a light-emitting diode chip configured to generate radiation, the light-emitting diode chip comprising:
a semiconductor layer sequence configured to generate the radiation;
electrical contact points on a mounting side;
a carrier body; and
an anti-wetting layer being exposed laterally at the light-emitting diode chip and being located between the semiconductor layer sequence and the carrier body and/or being located in a lateral direction next to the semiconductor layer sequence;
a filling permeable to the radiation; and
a reflector for the radiation,
wherein the anti-wetting layer has a repellent effect on at least one of a material of the reflector or of the filling,
wherein the filling and the reflector adjoin each other at the exposed anti-wetting layer, and
wherein the filling widens along a direction away from the mounting side so that an interface between the filling and the reflector is configured to reflect the radiation in a direction away from the carrier body.

17. The optoelectronic semiconductor component according to claim 16, further comprising:
a luminous substance body on a chip top side facing away from the mounting side of the light-emitting diode chip,
wherein side surfaces of the luminous substance body are directly covered by the filling and the luminous substance body is spaced apart from the reflector.

18. The optoelectronic semiconductor component according to claim 17,
wherein the luminous substance body terminates flush with the filling in the direction away from the mounting side, and
wherein a top face of the luminous substance body is free of the filling and free of the reflector.

19. The optoelectronic semiconductor component according to claim 16, wherein the anti-wetting layer is electrically separated from the contact points.

20. The optoelectronic semiconductor component according to claim 16, wherein the anti-wetting layer comprises one or more metal layers and has a total thickness of between 20 nm and 500 nm inclusive.

21. The optoelectronic semiconductor component according to claim 20, wherein the anti-wetting layer comprises one or more of the following metals: Au, Cu, Ni, Sn, or Pd.

22. The optoelectronic semiconductor component according to claim 16,
wherein the anti-wetting layer is part of a mirror for the radiation, and
wherein the anti-wetting layer is spaced apart from the semiconductor layer sequence.

23. The optoelectronic semiconductor component according to claim 16,
wherein the reflector is formed by a potting body composed of a matrix material permeable to the radiation and of light-scattering particles, and
wherein the reflector has a diffusely reflecting effect and is flush with the contact points at the mounting side.

24. The optoelectronic semiconductor component according to claim 23, wherein the filling essentially consists of a phenyl silicone and the matrix material comprises a methyl silicone so that the filling has a higher refractive index for the radiation than the matrix material.

25. The optoelectronic semiconductor component according to claim 16,
wherein the reflector is formed by a reflecting mirror layer which completely covers the filling at the interface, and
wherein the mirror layer is specularly reflective and has a thickness of at most 2 μm.

26. The optoelectronic semiconductor component according to claim 16,
wherein chip side surfaces of the light emitting diode chip are formed by a cast body at least on the mounting side, and
wherein the filling is spaced apart from the cast body and, in a region of the cast body, the chip side surfaces are covered directly and completely with the reflector.

27. The optoelectronic semiconductor component according to claim 16, wherein, on a side facing away from the mounting side, the filling is completely and the reflector is at least partially covered by a light decoupling body.

28. The optoelectronic semiconductor component according to claim 16,
wherein an average angle of the interface to a main radiation direction of the light-emitting diode chip lies between 40° and 70° inclusive, and
wherein each partial section of the interface has an angle with respect to the main radiation direction between 25° and 80° inclusive, seen in cross section.

29. The optoelectronic semiconductor component according to claim 16,
wherein, in a direction perpendicular to the mounting side, the filling has an extent between 2 μm and 50 μm inclusive and between 2% and 40% inclusive of a total thickness of the light-emitting diode chip, and
wherein an extent of the filling along the lateral direction is between 2 μm and 100 μm inclusive and between 0.5% and 25% of a total width of the light-emitting diode chip.

30. A method comprising:
providing a light-emitting diode chip for generating radiation, the light-emitting diode chip having a semiconductor layer sequence for generating the radiation, electrical contact points arranged on a mounting side, a carrier body and an anti-wetting layer;
forming a filling which is permeable to the radiation; and
forming a reflector for the radiation,
wherein the anti-wetting layer has a repellent effect for a material of the reflector or of the filling,
wherein the anti-wetting layer is exposed laterally at the light-emitting diode chip and is located between the semiconductor layer sequence and the carrier body and/or is located in a lateral direction next to the semiconductor layer sequence so that the anti-wetting layer is a boundary line for a material of the filling or of the reflector, and
wherein forming the filling and the reflector comprises forming the filling and the reflector directly abutting one another so that the filling widens along a direction away from the mounting side and so that the radiation is reflectable in a direction away from the carrier body.
